(19) United States
(12) Patent Application Publication
(10) Pub. No.: US 2025/0234728 A1
(43) Pub. Date: Jul. 17, 2025

(54) DISPLAY DEVICE

(71) Applicant: Samsung Display Co., LTD., Yongin-si (KR)

(72) Inventors: Da Sol JEONG, Yongin-si (KR); Young Deok SEO, Yongin-si (KR); Eun Ho SONG, Yongin-si (KR); Seok Hyun LIM, Yongin-si (KR); Seung Hwan CHO, Yongin-si (KR)

(73) Assignee: Samsung Display Co., LTD., Yongin-si (KR)

(21) Appl. No.: 18/894,692

(22) Filed: Sep. 24, 2024

(30) Foreign Application Priority Data
Jan. 15, 2024 (KR) 10-2024-0006170

(51) Int. Cl. H10K 59/131; H10K 59/122; H10K 59/124; H10K 102/00

(52) U.S. Cl. CPC H10K 59/131; H10K 59/122; H10K 59/124; H10K 2102/351

(57) ABSTRACT

A display device may include: a display area in which a pixel is disposed and a non- display area that corresponds to an area separate from the display area; a pixel circuit layer including a pixel circuit; a first electrode disposed on the pixel circuit layer; an insulating layer having at least a portion exposing the first electrode; a second electrode disposed in the display area; and a connection electrode integrally formed with the second electrode, the connection electrode disposed in the non-display area. The insulating layer includes: a first insulating layer disposed in the display area; and a second insulating layer disposed in the non-display area. The second insulating layer is in contact with at least a portion of the connection electrode.

### CROSS-REFERENCE TO RELATED APPLICATION

This application claims priority to and the benefit of Korean patent application No. 10-2024-0006170 under 35 U.S.C. § 119, filed on Jan. 15, 2024 in the Korean Intellectual Property Office, the entire content of which is incorporated herein by reference.

### BACKGROUND

### 1. Technical Field

The disclosure generally relates to a display device.

### 2. Description of the Related Art

With the development of information technologies, the importance of a display device that is a connection medium between a user and information increases.

The display device may include a display area in which pixels are disposed for displaying an image, and a non-display area as an area separate from the display area. Also, the display device may include electrodes (e.g., a cathode electrode) for supplying a power source to the pixels, and the electrodes of the display device may be deposited in the display area and a partial area of the non-display area of the display device.

When the electrodes of the display device are not appropriately deposited, the electrodes may be disconnected, and the power source may not be supplied to the pixel.

### SUMMARY

Embodiments provide a display device capable of reducing a risk that an electrode (e.g., a cathode electrode) will be disconnected.

In accordance with an aspect of the disclosure, there is provided a display device including: a display area in which a pixel is disposed and a non-display area that corresponds to an area separate from the display area; a pixel circuit layer including a pixel circuit; a first electrode disposed on the pixel circuit layer; an insulating layer having at least a portion exposing the first electrode; a second electrode disposed in the display area; and a connection electrode integrally formed with the second electrode, the connection electrode disposed in the non-display area, wherein the insulating layer includes: a first insulating layer disposed in the display area; and a second insulating layer disposed in the non-display area, and wherein the second insulating layer is in contact with at least a portion of the connection electrode.

The display device may further include a metal layer disposed in the non-display area, the metal layer being disposed on the pixel circuit layer. At least a portion of the second insulating layer may overlap at least a portion of the metal layer in a plan view. The second insulating layer may expose a top surface of the metal layer. An end portion of the second insulating layer may be in contact with the connection electrode.

The connection electrode may be in contact with at least a portion of the top surface of the metal layer.

The metal layer may include at least one of Al, Ag, and Cu.

The metal layer may have a thickness in a range of 500 Å to 1000 Å.

The insulating layer may include a lower layer and an upper layer disposed on the lower layer. At least a portion of the insulating layer may extend from the display area to the non-display area.

The lower layer may include: a first lower layer; and a second lower layer disposed on the first lower layer. The upper layer may include: a first upper layer; a second upper layer disposed on the first upper layer; and a third upper layer disposed on the second upper layer.

Each of the first lower layer, the second lower layer, the first upper layer, the second upper layer, and the third upper layer may include at least one of silicon oxide (SiOₓ) and silicon nitride (SiNₓ). Each of the first lower layer, the second lower layer, the first upper layer, the second upper layer, and the third upper layer may have a thickness in a range of about 100 Å to about 600 Å.

At least a portion of the second insulating layer may be connected to at least a portion of the first insulating layer, so that at least a portion of the insulating layer is disposed in the display area and the non-display area.

The pixel circuit layer may include: a first protective layer; and a second protective layer disposed on the first protective layer. The second protective layer may be disposed at an uppermost portion of the pixel circuit layer. At least a portion of the second insulating layer may be in contact with the second protective layer.

At least a portion of the second insulating layer may cover a side surface of the metal layer.

The pixel circuit layer may include: a contact hole penetrating at least a portion of the pixel circuit layer; a first conductive layer disposed in the display area; and a second conductive layer disposed in the non-display area. The metal layer may be electrically connected to the second conductive layer through the contact hole.

In accordance with another aspect of the disclosure, there is provided a display device including: a display area in which a pixel is disposed and a non-display area that corresponds to an area separate from the display area; a pixel circuit layer including a pixel circuit; a first power line and a second power line, electrically connected to the pixel circuit; a first electrode disposed on the pixel circuit layer; an insulating layer having at least a portion exposing the first electrode; a second electrode disposed in the display area; and a metal layer disposed on the pixel circuit layer in the non-display area, wherein the insulating layer includes: a first insulating layer disposed in the display area; and a second insulating layer disposed in the non-display area, wherein the second insulating layer is in contact with at least a portion of the metal layer, and wherein the non-display area includes a contact area in which the second power line and a connection electrode are electrically connected to each other.

The display device may further include the connection electrode integrally formed with the second electrode, the connection electrode being disposed in the non-display area. The connection electrode may be in contact with at least a portion of a top surface of the metal layer. The contact area may include: a first contact area disposed at a first side of the display area; a second contact area disposed at a second side of the display area; a third contact area disposed at a third side of the display area; and a fourth contact area disposed at a fourth side of the display area.

The metal layer may include at least one of Al, Ag, and Cu. The metal layer may have a thickness in a range of about 500 Å to about 1000 Å. The contact area may include: a fifth contact area disposed between the first contact area and the second contact area; and a sixth contact area disposed between the third contact area and the fourth contact area.

The insulating layer may include a lower layer and an upper layer disposed on the lower layer. The lower layer may include: a first lower layer; and a second lower layer disposed on the first lower layer. The upper layer may include: a first upper layer; a second upper layer disposed on the first upper layer; and a third upper layer disposed on the second upper layer. The contact area may surround at least a portion of the display area.

Each of the first lower layer, the second lower layer, the first upper layer, the second upper layer, and the third upper layer may include at least one of silicon oxide (SiOₓ) and silicon nitride (SiNₓ), and have a thickness in a range of about 100 Å to about 600 Å.

At least a portion of the second insulating layer may be connected to at least a portion of the first insulating layer, so that at least a portion of the insulating layer is disposed in the display area and the non-display area. At least a portion of the second insulating layer may overlap at least a portion of the metal layer in a plan view.

The pixel circuit layer may include: a contact hole penetrating at least a portion of the pixel circuit layer; a first conductive layer disposed in the display area; and a second conductive layer disposed in the non-display area. The metal layer may be electrically connected to the second conductive layer through the contact hole.

The non-display area may surround at least a portion of the display area.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, the sizes, thicknesses, and dimensions of the elements may be exaggerated for ease of description and for clarity of illustration. It will be understood that when an element is referred to as being “between” two elements, it can be the only element between the two elements, or one or more intervening elements may also be present. Like reference numerals refer to like elements throughout.

FIGS. 1 to 3 are schematic plan views illustrating a display device in accordance with an embodiment that is constructed according to principles of the disclosure.

FIGS. 4 and 5 are schematic plan views illustrating embodiments of a pixel shown in FIG. 1.

FIG. 6 is a schematic sectional view of the display device taken along line A-A′ shown in FIG. 1.

FIG. 7 is an enlarged schematic sectional view illustrating a lower layer and an upper layer, which are shown in FIG. 6.

FIGS. 8A and 8B are sectional views illustrating embodiments of a light emitting structure included in a light emitting element shown in FIG. 6.

FIG. 9 is a schematic sectional view of the display device taken along line B-B′ shown in FIG. 1.

FIG. 10 is a schematic sectional view of a display device taken along the line B-B′ shown in FIG. 1 in accordance with another embodiment.

FIG. 11 is a schematic block diagram illustrating an electrical connection structure of a light emitting element in accordance with an embodiment.

FIG. 12 is a schematic block diagram illustrating a display system in accordance with an embodiment.

FIG. 13 is a schematic perspective view illustrating an application example of the display system shown in FIG. 12.

### DETAILED DESCRIPTION OF THE EMBODIMENTS

The disclosure may apply various changes and different shape, therefore only illustrate in details with particular examples. However, the examples do not limit to certain shapes but apply to all the change and equivalent material and replacement. The drawings included are illustrated a fashion where the figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The term “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

The term “and/or” includes all combinations of one or more of which associated configurations may define. For example, “A and/or B” may be understood to connote “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

The disclosure generally relates to a display device. Hereinafter, a display device in accordance with an embodiment will be described with reference to the accompanying drawings.

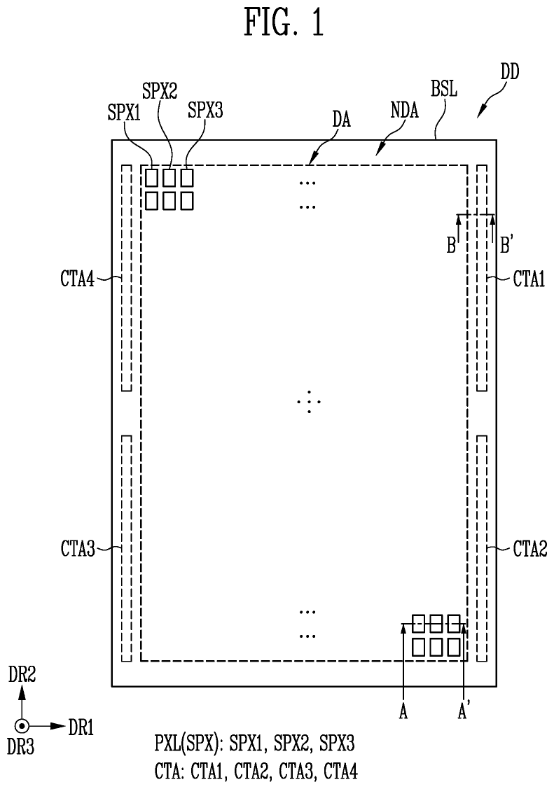

FIGS. 1 to 3 are schematic plan views illustrating a display device in accordance with an embodiment.

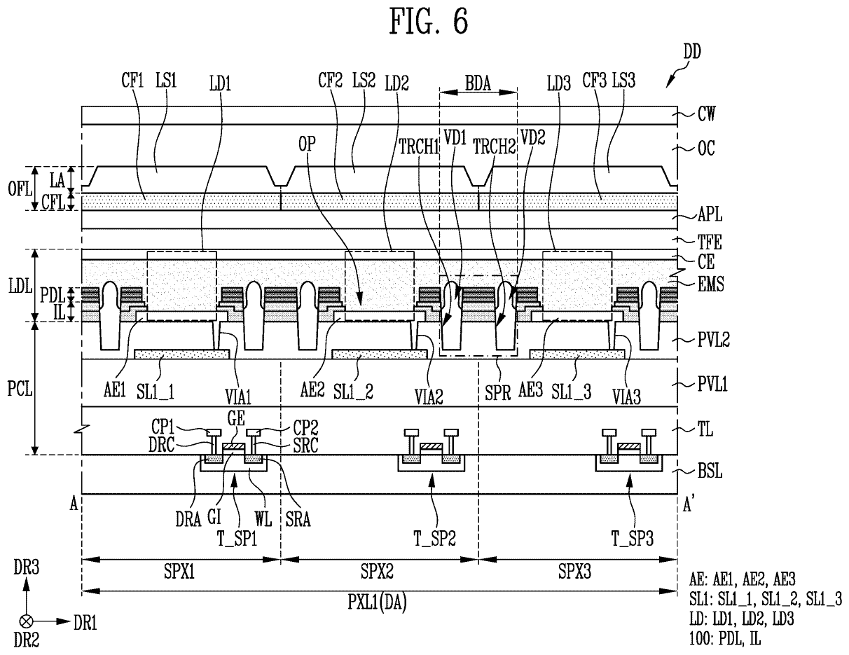

Referring to FIG. 1, the display device DD is configured to emit light. The display device DD includes a light emitting element LD (see FIG. 6). In some embodiments, the display device DD may be provided in various shapes. For example, the display device DD may be formed in a rectangular plane having short sides in a first direction DR1 and long sides in a second direction DR2 intersecting the first direction DR1. In the embodiment, the first direction DR1 may be a row direction of pixels PXL. The second direction DR2 may be a column direction of the pixels PXL. A third direction DR3 may be a display direction of the display device DD (i.e., a thickness direction of the display device DD). In some embodiments, the display device DD may be applied to smartphones, notebook computers, tablet personal computers (PCs), wearable devices (e.g., head-mounted devices, smart watches, smart glasses, and the like), televisions, vehicle infortainment systems, or the like, and be applied to various embodiments in addition thereto.

The display device DD may include a base layer BSL and pixels PXL disposed on the base layer BSL. The display device DD may further include a driving circuit (e.g., a scan driver and a data driver) for driving the pixels PXL, lines, pads, and the like.

The display device DD may include a display area DA and a non-display area NDA. The non-display area NDA may correspond to an area separate from the display area DA. The non-display area NDA may surround at least a portion of the display area DA.

The base layer BSL may form a base member of the display device DD. The base layer BSL may be a rigid or flexible substrate or film. For example, the base layer BSL may be a rigid substrate made of glass or tempered glass. As another example, the base layer BSL may include materials having flexibility, and be a flexible substrate (or thin film) made of a plastic or metal material or at least one insulating layer. However, the material and/or property of the base layer BSL are/is not particularly limited.

In some embodiments, the base layer BSL may be substantially transparent. The term “substantially transparent” may connote that light can be transmitted with a certain transmittance or more. In another embodiment, the base layer BSL may be translucent or opaque. Also, the base layer BSL may include a reflective material in some embodiments.

In some embodiments, the base layer BSL may be provided as a silicon substrate. In some embodiments, the base layer BSL may include a silicon wafer substrate formed using a semiconductor process. The base layer BSL may include a semiconductor material suitable for forming circuit elements. For example, the semiconductor material may include silicon, germanium, and/or silicon-germanium. The base layer BSL may be provided from a bulk wafer, an epitaxial layer, a Silicon On Insulator (SOI), a Semiconductor On Insulator (SeOI), or the like. In another embodiment, the base layer BSL may include a glass substrate. In still another embodiment, the base layer BSL may include a polyimide (PI) substrate.

The display area DA may correspond to an area in which the pixels PXL are disposed. The non-display area NDA may correspond to an area in which the pixels PXL are not disposed. The driving circuit, the lines, and the pads, which are connected to the pixels PXL of the display area DA, may be disposed in the non-display area NDA.

In some embodiments, the pixels PXL (or sub-pixels SPX) may be arranged according to a stripe arrangement structure, a PENTILE™ arrangement structure, or the like. However, the embodiments described herein are necessarily not limited thereto.

In some embodiments, the pixel PXL (or sub-pixels SPX) may include a first sub-pixel SPX1, a second sub-pixel SPX2, and a third sub-pixel SPX3. At least one first sub-pixel SPX1, at least one second sub-pixel SPX2, and at least one third sub-pixel SPX3 may form one pixel unit capable of emitting lights of various colors. In FIG. 1, it is illustrated that each pixel PXL includes three sub-pixels SPX1, SPX2, and SPX3, i.e., the first sub-pixel SPX1, the second sub-pixel SPX2, and the third sub-pixel SPX3. However, the embodiment described herein is not limited thereto.

In some embodiments, the sub-pixels SPX may have a rectangular, square, or rhombic planar shape. For example, each of the first sub-pixel SPX1, the second sub-pixel SPX2, and the third sub-pixel SPX3 may have a rectangular planar shape having short sides in the first direction DR1 and long sides in the second direction DR2 as shown in FIG. 1. As another example, the sub-pixels SPX may have a square or rhombic planar shape including sides having a same length in the first direction DR1 and the second direction DR2.

In some embodiments, areas of the first sub-pixel SPX1, the second sub-pixel SPX2, and the third sub-pixel SPX3 may be substantially the same, but the embodiment is not limited thereto. For example, at least one of the areas of the first sub-pixel SPX1, the second sub-pixel SPX2, and the third sub-pixel SPX3 may be different from an area of another of the first sub-pixel SPX1, the second sub-pixel SPX2, and the third sub-pixel SPX3. As another example, any two of the area of the first sub-pixel SPX1, the area of the second sub-pixel SPX2, and the area of the third sub-pixel SPX3 may be substantially the same, and the other of the area of the first sub-pixel SPX1, the area of the second sub-pixel SPX2, and the area of the third sub-pixel SPX3 may be different from the two of the area of the first sub-pixel SPX1, the area of the second sub-pixel SPX2, and the area of the third sub-pixel SPX3. As another example, the area of the first sub-pixel SPX1, the area of the second sub-pixel SPX2, and the area of the third sub-pixel SPX3 may be different from one another.

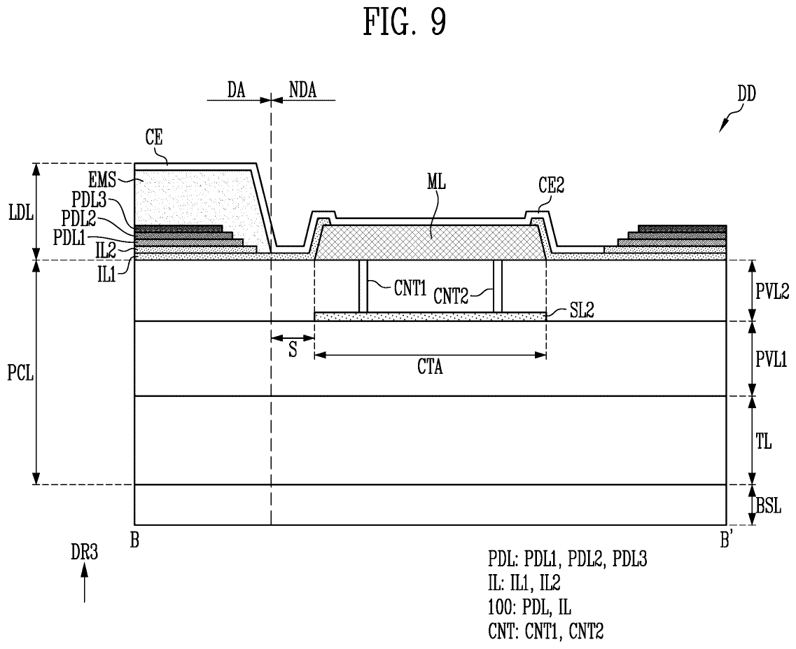

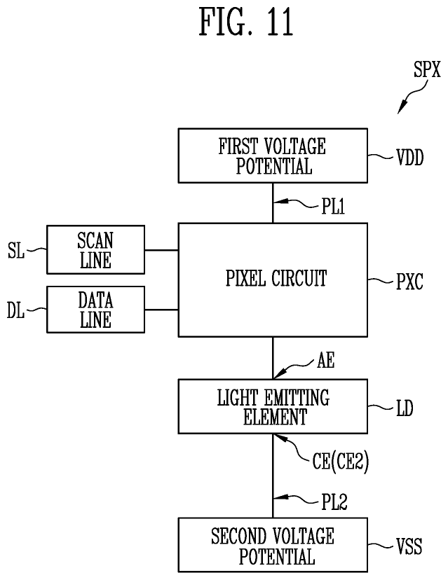

The non-display area NDA may include a contact area CTA. The contact area CTA may be an area in which a connection electrode CE2 (see FIG. 9) for supplying a power source to one electrode (e.g., a second electrode CE (see FIG. 6)) of the light emitting element LD and the lines (e.g., a second power line PL2 (see FIG. 11)) connected to the pixels PXL, which are disposed in the non-display area NDA, are electrically connected to each other. For example, the contact area CTA may be an area in which the connection electrode CE2 for supplying a power source to the one electrode (e.g., the second electrode CE) of the light emitting element LD and the lines (e.g., the second power line PL2) connected to the pixels PXL, which are disposed in the non-display area NDA, are physically in contact with each other.

The contact area CTA may include one or more areas spaced apart from each other in a plan view. The number of one or more areas forming the contact area CTA is not particularly limited.

In accordance with an embodiment (see FIG. 1), a contact area CTA may include a first contact area CTA1, a second contact area CTA2, a third contact area CTA3, and a fourth contact area CTA4.

The first contact area CTA1 may be disposed at a first side (e.g., a right upper end) of the non-display area NDA and the display area DA. The second contact area CTA2 may be disposed at a second side (e.g., a right lower end) of the non-display area NDA and the display area DA. The third contact area CTA3 may be disposed at a third side (e.g., a left lower end) of the non-display area NDA and the display area DA. The fourth contact area CTA4 may be disposed at a fourth side (e.g., a left upper end) of the non-display area NDA and the display area DA.

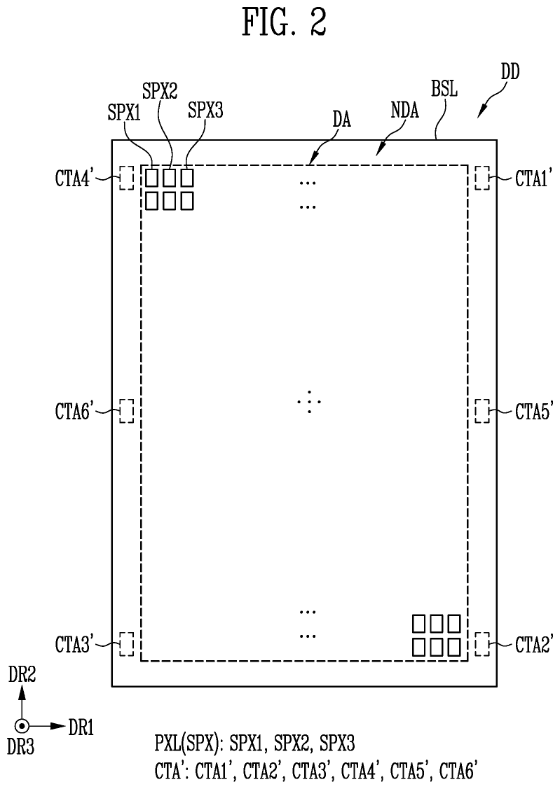

In accordance with an embodiment (see FIG. 2), a contact area CTA′ may include a first contact area CTA1′, a second contact area CTA2′, a third contact area CTA3′, a fourth contact area CTA4′, a fifth contact area CTA5′, and a sixth contact area CTA6′.

The first contact area CTA1′ may be disposed at a first side (e.g., a right upper end) of the non-display area NDA and the display area DA. The second contact area CTA2′ may be disposed at a second side (e.g., a right lower end) of the non-display area NDA and the display area DA. The third contact area CTA3′ may be disposed at a third side (e.g., a left lower end) of the non-display area NDA and the display area DA. The fourth contact area CTA4′ may be disposed at a fourth side (e.g., a left upper end) of the non-display area NDA and the display area DA. The fifth contact area CTA5′ may be disposed at a fifth side (e.g., a right center) of the non-display area NDA and the display area DA. The sixth contact area CTA6′ may be disposed at a sixth side (e.g., a left center) of the non-display area NDA and the display area DA.

The contact area CTA′ shown in FIG. 2 may have an area smaller than an area of the contact area CTA shown in FIG. 1. However, the embodiment is not limited thereto, and the area of the contact area CTA may be changed in different implementations.

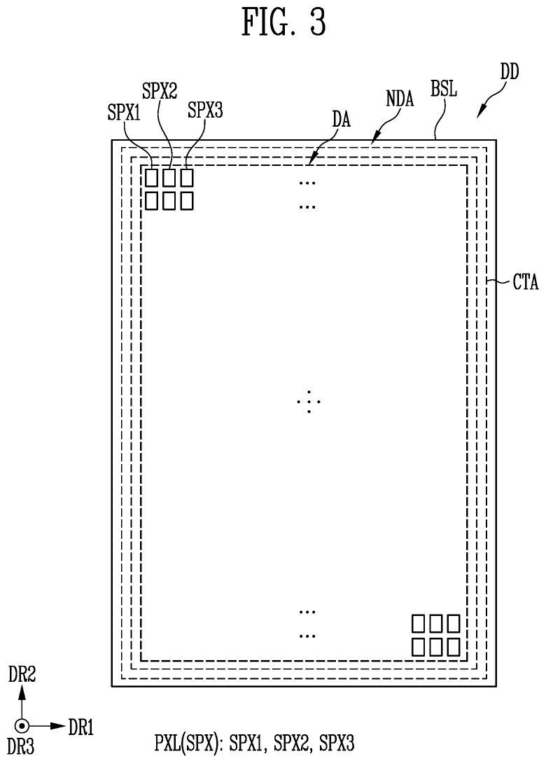

In accordance with an embodiment (see FIG. 3), a contact area CTA may include a single area. For example, the contact area CTA may be formed as one area. The contact area CTA may surround at least a portion of the display area DA. In some embodiments, the contact area CTA may have a shape corresponding to an edge portion of the display area DA.

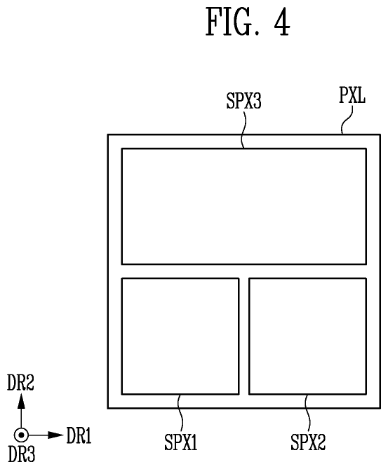

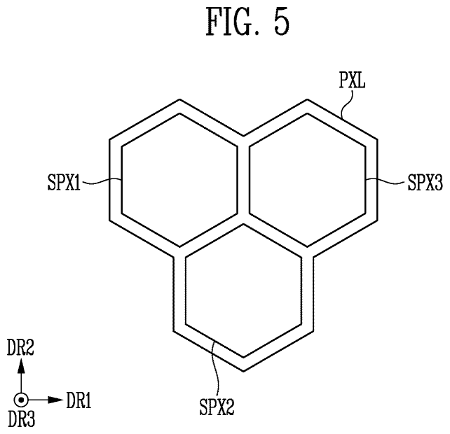

FIGS. 4 and 5 are schematic plan views illustrating embodiments of the pixel shown in FIG. 1. Hereinafter, structures of the pixel PXL in accordance with embodiments will be described with reference to FIGS. 4 and 5.

Referring to FIG. 4, a first sub pixel SPX1 may be arranged with any one of a second sub-pixel SPX2 and a third sub-pixel SPX3 in the first direction DR1, and be arranged with the other of the second sub-pixel SPX2 and the third sub-pixel SPX3 in the second direction DR2. For example, the first sub-pixel SPX1 may be arranged with the second sub-pixel SPX2 in the first direction DR1, and be arranged with the third sub-pixel SPX3 in the second direction DR2.

In some embodiments, the third sub-pixel SPX3 may be adjacent to the first sub-pixel SPX1 and the second sub-pixel SPX2 along the second direction DR2. In some embodiments, areas of the first and second sub-pixels SPX1 and SPX2 may be substantially the same, and an area of the third sub-pixel SPX3 may be different from each of the areas of the first and second sub-pixels SPX1 and SPX2. For example, the area of the third sub-pixel SPX3 may be wider than each of the areas of the first and second sub-pixels SPX1 and SPX2.

Referring to FIG. 5, each of a first sub-pixel SPX1, a second sub-pixel SPX2, and a third sub-pixel SPX3 may have a hexagonal (or regular hexagonal) planar shape. In some embodiments, adjacent two surfaces among six surfaces of each of the first sub-pixel SPX1, the second sub-pixel SPX2, and the third sub-pixel SPX3 may face one surface of each of adjacent sub-pixels SPX.

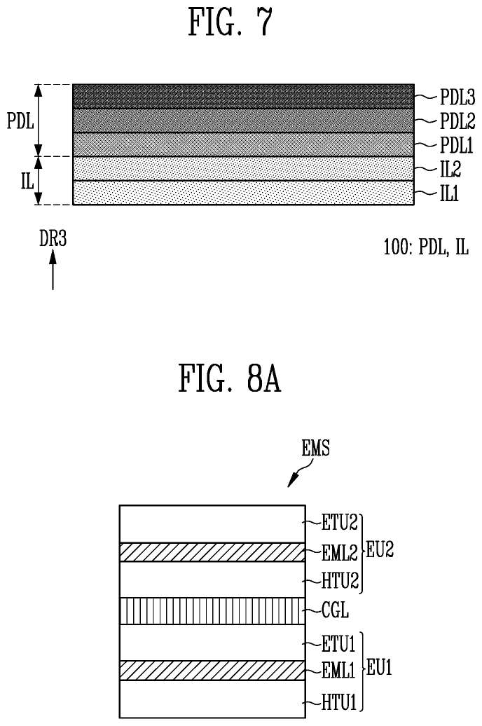

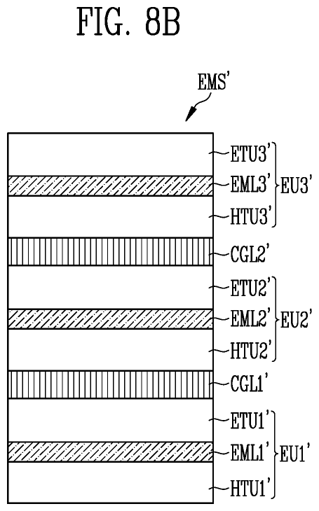

FIG. 6 is a schematic sectional view of the display device taken along line A-A′ shown in FIG. 1. FIG. 6 may be a drawing illustrating a sectional view in the display area DA of the display device DD. FIG. 7 is an enlarged schematic sectional view illustrating a lower layer and an upper layer, which are shown in FIG. 6. FIGS. 8A and 8B are sectional views illustrating embodiments of a light emitting structure included in a light emitting element shown in FIG. 6. Hereinafter, the display device DD in the display area DA will be described with reference to FIGS. 6, 7, 8A, and 8B.

Referring to FIG. 6, a base layer BSL and a pixel circuit layer PCL disposed on the base layer BSL may be provided.

The base layer BSL may be a base member of the above-described display device DD. The base layer BSL may include a silicon wafer substrate formed using a semiconductor process. For example, the base layer BSL may include silicon, germanium, and/or silicon-germanium. Accordingly, the display device DD may be designated as an OLED on Silicon (OLEDoS) display device.

The pixel circuit layer PCL may include a transistor layer TL, a first protective layer PVL1, and a second protective layer PVL2.

The transistor layer TL may be disposed on the base layer BSL. The base layer BSL and the transistor layer TL may include circuit elements of each of a first sub-pixel SPX1, a second sub-pixel SPX2, and a third sub-pixel SPX3. For example, the base layer BSL and the transistor layer TL may include a transistor T_SP1 of the first sub-pixel SPX1, a transistor T_SP2 of the second sub-pixel SPX2, and a transistor T_SP3 of the third sub-pixel SPX3. The transistor T_SP1 of the first sub-pixel SPX1 may be any one of transistors included in a sub-pixel circuit of the first sub-pixel SPX1, the transistor T_SP2 of the second sub-pixel SPX2 may be any one of transistors included in a sub-pixel circuit of the second sub-pixel SPX2, and the transistor T_SP3 of the third sub-pixel SPX3 may be any one of transistors included in a sub-pixel circuit of the third sub-pixel SPX3.

In some embodiments, the transistors may include complementary metal-oxide semiconductor (CMOS) circuit elements. In FIG. 6, for clear and brief description, one of the transistors of each sub-pixel is illustrated, and the other circuit elements are omitted for sake of brevity and clarity.

The transistors T_SP1 of the first sub-pixel SPX1 may include a source region SRA, a drain region DRA, and a gate electrode GE.

The source region SRA and the drain region DRA may be disposed in the base layer BSL. A well WL formed through an ion implantation process may be disposed in the base layer BSL, and the source region SRA and the drain region DRA may be disposed in the well WL to be spaced apart from each other. A region between the source region SRA and the drain region DRA in the well WL may be defined as a channel region.

The gate electrode GE may overlap the channel region between the source region SRA and the drain region DRA, and be disposed in the transistor layer TL. The gate electrode GE may be spaced apart from the well WL or the channel region by an insulating material such as a gate insulating layer GI. The gate electrode GE may include a conductive material.

One or more layers included in the transistor layer TL may include insulating layers and conductive patterns disposed between the insulating layers, and the conductive patterns may include first and second conductive patterns CP1 and CP2. The first conductive pattern CP1 may be electrically connected to the drain region DRA through a drain connection portion DRC penetrating one or more insulating layers. The second conductive pattern CP2 may be electrically connected to the source region SRA through a source connection portion SRC penetrating one or more insulating layers.

Each of the transistor T_SP2 of the second sub-pixel SPX2 and the transistor T_SP3 of the third sub-pixel SPX3 may be configured identically to the transistor T_SP1 of the first sub-pixel SPX1.

As such, the base layer BSL and the transistor layer TL may include circuit elements of each of the first sub-pixel SPX1, the second sub-pixel SPX2, and the third sub-pixel SPX3.

The first protective layer PVL1 may be disposed on the transistor layer TL. The first protective layer PVL1 covers the transistor layer TL, and may have an entirely flat surface. The first protective layer PVL1 is configured to planarize step differences on the transistor layer TL. The first protective layer PVL1 may include at least one of silicon oxide (SiOₓ), silicon nitride (SiNₓ), and silicon carbon nitride (SiCN), but embodiments are not limited thereto.

On the first protective layer PVL1, a (1_1)th conductive layer SL1_1, a (1_2)th conductive layer SL1_2, and a (1_3)th conductive layer SL1_3 may be disposed in the first sub-pixel SPX1, the second sub-pixel SPX2, and the third sub-pixel SPX3, respectively. Each of the (1_1)th conductive layer SL1_1, the (1_2)th conductive layer SL1_2, and the (1_3)th conductive layer SL1_3 may be in contact with a circuit element disposed in the transistor layer TL through a via penetrating the first protective layer PVL1.

In the embodiment described herein, a first conductive layer SL1 is a conductive layer disposed in the display area DA, and may supply an electrical signal to a first electrode AE of a light emitting element LD.

In order to planarize step differences between the (1_1)th conductive layer SL1_1, the (1_2)th conductive layer SL1_2, and the (1_3)th conductive layer SL1_3, the second protective layer PVL2 may be disposed over the (1_1)th conductive layer SL1_1, the (1_2)th conductive layer SL1_2, and the (1_3)th conductive layer SL1_3. The second protective layer PVL2 entirely covers the (1_1)th conductive layer SL1_1, the (1_2)th conductive layer SL1_2, the (1_3)th conductive layer SL1_3, and the first protective layer PVL1, and have a flat surface.

In some embodiments, the second protective layer PVL2 may be a via layer including a via (e.g., a first via VIA1, a second via VIA2, and a third via VIA3) for electrically connecting the light emitting element LD and the first conductive layer SL1 to each other and a contact hole CNT (see FIG. 9) for electrically connecting a connection electrode CE2 (see FIG. 9) and a second conductive layer SL2 (see FIG. 9) to each other. In some embodiments, the second protective layer PVL2 may be disposed at an outermost portion (or uppermost portion) of the pixel circuit layer PCL, and planarize a surface of the pixel circuit layer PCL.

A light emitting element layer LDL may be disposed on the second protective layer PVL2. The light emitting element layer LDL may include first electrodes AE, a lower layer IL, an upper layer PDL, a light emitting structure EMS, and a second electrode CE.

The first electrodes AE may be disposed on the second protective layer PVL2. The first electrodes AE1 to AE3 may include a (1_1)th electrode AE1, a (1_2)th electrode AE2, and a (1_3)th electrode AE3. The (1_1)th electrode AE1, the (1_2)th electrode AE2, and the (1_3)th electrode AE3, which respectively overlap the (1_1)th conductive layer SL1_1, the (1_2)th conductive layer SL1_2, and the (1_3)th conductive layer SL1_3, may be disposed on the second protective layer PVL2. The (1_1)th electrode AE1 may be connected to the (1_1)th conductive layer SL1_1 through the first via VIA1 penetrating the second protective layer PVL2. The (1_2)th electrode AE2 may be connected to the (1_2)th conductive layer SL1_2 through the second via VIA2 penetrating the second protective layer PVL2. The (1_3)th electrode AE3 may be connected to the (1_3)th conductive layer SL1_3 through the third via VIA3 penetrating the second protective layer PVL2.

In embodiments, each of the (1_1)th electrode AE1, the (1_2)th electrode AE2, and the (1_3)th electrode AE3 may be an anode electrode of the light emitting element LD. The (1_1)th electrode AE1, the (1_2)th electrode AE2, and the (1_3)th electrode AE3 may include at least one of transparent conductive materials such as indium tin oxide (ITO), indium zinc oxide (IZO), zinc oxide (ZnOₓ), indium gallium zinc oxide (IGZO), and indium tin zinc oxide (ITZO). However, the embodiment is not limited thereto. For example, the (1_1)th electrode AE1, the (1_2)th electrode AE2, and the (1_3)th electrode AE3 may include at least one of Al, Ag, and Cu, and further include at least one of indium tin oxide (ITO), titanium (Ti), and titanium nitride (TiN).

In some embodiments, the first electrode AE may have a single-layer structure including at least one of Al, Ag, and Cu. In some embodiments, the first electrode AE may have a triple-layer structure in which a layer including at least one of Al, Ag, and Cu is stacked on a layer including at least one of indium tin oxide (ITO), titanium (Ti), and titanium nitride (TiN), and a layer including at least one of Al, Ag, and Cu is stacked on the layer including at least one of Al, Ag, and Cu. However, the embodiment is not limited thereto, and the first electrode AE may include a metal having a high reflectivity.

An insulating layer 100 may be disposed on portions of the first electrode AE and the second protective layer PVL2. The insulating layer 100 may include the lower layer IL and the upper layer PDL. However, the embodiment is not limited thereto, and the lower layer IL may be omitted in some embodiments.

The lower layer IL may be disposed downwardly of the upper layer PDL. Hereinafter, in the embodiments described herein, a lower direction is defined as the opposite direction of the third direction DR3, and an upper direction is defined as the third direction DR3.

The lower layer IL and the upper layer PDL may include an opening OP exposing a portion of the first electrode AE. The lower layer IL and the upper layer PDL may be a pixel defining layer defining an emission area, and the opening OP may define an emission area of each of the first sub-pixel SPX1, the second sub-pixel SPX2, and the third sub-pixel SPX3.

Referring to FIG. 7, in embodiments, the lower layer IL and the upper layer PDL may include one or more inorganic insulating layers. Each of the inorganic insulating layers may include at least one of silicon oxide (SiOₓ) and silicon nitride (SiNₓ). For example, the lower layer IL may include a first lower layer IL1 and a second lower layer IL2, which are sequentially stacked, and each of the first lower layer IL1 and the second lower layer IL2 may include at least one of silicon oxide (SiOₓ) and silicon nitride (SiNₓ).

For example, the upper layer PDL may include a first upper layer PDL1, a second upper layer PDL2, and a third upper layer PDL3, which are sequentially stacked on the lower layer IL, and each of the first upper layer PDL1, the second upper layer PDL2, and the third upper layer PDL3 may include at least one of silicon oxide (SiOₓ) and silicon nitride (SiNₓ). However, the embodiment is not limited thereto, and the number of layers constituting the lower layer IL and the upper layer PDL may be changed. For example, the lower layer IL may be omitted in some implementations, and the upper layer PDL may include the first upper layer PDL1, the second upper layer PDL2, and the third upper layer PDL3. As another example, in some embodiments, the upper layer PDL may be formed as a single layer including the first upper layer PDL1 or a double layer including the first upper layer PDL1 and the second upper layer PDL2.

In some embodiments, each of the first lower layer IL1, the second lower layer IL2, the first upper layer PDL1, the second upper layer PDL2, and the third upper layer PDL3 may have a thickness in a range of about 100 Å to about 600 Å.

A separator SPR may be provided in a boundary area BDA between sub-pixels adjacent to each other.

The separator SPR may cause that a discontinuity is formed in the light emitting structure EMS in the boundary area BDA. For example, the light emitting structure EMS may be cut or curved by the separator SPR in the boundary area BDA.

The separator SPR may be provided in or on the upper layer PDL and the lower layer IL. The upper layer PDL and the lower layer IL may include one or more trenches TRCH1 and TRCH2 as the separator SPR in the boundary area BDA. In embodiments, as shown in FIG. 6, the one or more trenches TRCH1 and TRCH2 may penetrate the upper layer PDL and the lower layer IL and partially penetrate the second protective layer PVL2. However, the embodiment is not limited thereto.

Due to first trenches TRCH1 and second trenches TRCH2, discontinuities such as a first void VD1 and a second void VD2, may be formed in the light emitting structure EMS in the boundary area BDA. Some layers stacked in the light emitting structure EMS may be cut or curved by first voids VD1 and second voids VD2. For example, at least one charge generation layer included in the light emitting structure EMS may be cut in the first voids VD1 and the second voids VD2. As such, due to the first and second trenches TRCH1 and TRCH2, portions of the light emitting structure EMS, which are included in the first sub-pixel SPX1, the second sub-pixel SPX2, and the third sub-pixel SPX3, may be at least partially separated from each other.

In FIG. 6, it is illustrated that the first and second voids VD1 and VD2 are formed in the light emitting structure EMS in the boundary area BDA. However, this is merely illustrative, and embodiments are not limited thereto. For example, a valley having a concave shape may be formed in the light emitting structure EMS in the boundary area BDA. The discontinuities formed in the light emitting structure EMS may be variously changed according to shapes of the first and second trenches TRCH1 and TRCH2.

In some embodiments, the light emitting structure EMS may be formed through a process such as vacuum deposition or inkjet printing. A same material as the light emitting structure EMS may be located on bottom surfaces of the first and second trenches TRCH1 and TRCH2, which are adjacent to the first protective layer PVL1.

The light emitting structure EMS may be disposed on the first electrode AE exposed by the opening OP. The light emitting structure EMS fills the opening OP, and may be entirely disposed within the first sub-pixel SPX1, the second sub-pixel SPX2, and the third sub-pixel SPX3.

The light emitting structure EMS may be at least partially cut or curved by the separator SPR in the boundary area BDA. Accordingly, in an operation of the display device DD, a current leaked to a sub-pixel adjacent to each of the first sub-pixel SPX1, the second sub-pixel SPX2, and the third sub-pixel SPX3 from each of the first sub-pixel SPX1, the second sub-pixel SPX2, and the third sub-pixel SPX3 through the layers included in the light emitting structure EMS can decrease. Thus, light emitting elements LD can operate with relatively high reliability.

Referring to FIG. 8A, in some embodiments, the light emitting structure EMS may have a tandem structure in which a first light emitting structure EU1 and a second light emitting structure EU2 are stacked. The light emitting structure EMS may be configured substantially identically in each of first to third light emitting elements LD1 to LD3 shown in FIG. 6.

Each of the first light emitting structure EU1 and the second light emitting structure EU2 may include a light generation layer generating light according to an applied current. The first light emitting structure EU1 may include a first light emitting layer EML1, a first electron transport unit ETU1, and a first hole transport unit HTU1. The first light emitting layer EML1 may be disposed between the first electron transport unit ETU1 and the first hole transport unit HTU1. The second light emitting structure EU2 may include a second light emitting layer EML2, a second electron transport unit ETU2, and a second hole transport unit HTU2. The second light emitting layer EML2 may be disposed between the second electron transport unit ETU2 and the second hole transport unit HTU2.

Each of the first and second hole transport units HTU1 and HTU2 may include at least one of a hole injection layer and a hole transport layer. Each of the first and second hole transport units HTU1 and HTU2 may further include a hole buffer layer, an electron blocking layer, and the like, in some implementations. The first and second hole transport units HTU1 and HTU2 may have a same configuration or have different configurations.

Each of the first and second electron transport units ETU1 and ETU2 may include at least one of an electron injection layer and an electron transport layer. Each of the first and second electron transport units ETU1 and ETU2 may further include an electron buffer layer, a hole blocking layer, and the like, in some implementations. The first and second electron transport units ETU1 and ETU2 may have a same configuration or have different configurations.

A connection layer, which may be provided in the form of a charge generation layer CGL, may be disposed between the first light emitting structure EU1 and the second light emitting structure EU2 to connect the first light emitting structure EU1 and the second light emitting structure EU2 to each other. In embodiments, the charge generation layer CGL may have a stacked structure of a p-dopant layer and an n-dopant layer. For example, the p-dopant layer may include a p-type dopant such as HAT-CN, TCNQ or NDP-9, and the n-dopant layer may include an alkali metal, an alkali earth metal, a lanthanide-based metal, or any combination thereof. However, embodiments are not limited thereto.

In embodiments, the first light emitting layer EML1 and the second light emitting layer EML2 may generate lights of different colors. Lights respectively emitted from the first light emitting layer EML1 and the second light emitting layer EML2 may be mixed together, to be viewed as white light. For example, the first light emitting layer EML1 may generate light of a blue color, and the second light emitting layer EML2 may generate light of a yellow color. In embodiments, the second light emitting layer EML2 may include a structure in which a first sub-light emitting layer configured to generate light of a red color and a second sub-light emitting layer configured to generate light of a green color are stacked. The light of the red color and the light of the green color may be mixed together to provide the light of the yellow color. An intermediate layer configured to perform a function of transporting holes and/or a function of blocking transportation of electrons may be further disposed between the first and second sub-light emitting layers.

In other embodiments, the first light emitting layer EML1 and the second light emitting layer EML2 may generate light of same color.

In the above, although an embodiment in which the light emitting structure EMS has the tandem structure in which the first light emitting structure EU1 and the second light emitting structure EU2 are stacked has been illustrated, the embodiment is not limited thereto. In some embodiments, referring to FIG. 8B, a light emitting structure EMS′ may a tandem structure in which first to third light emitting structures EU1′ to EU3′ are stacked. The light emitting structure EMS′ may be configured substantially identically in each of the first to third light emitting elements LD1 to LD3 shown in FIG. 6.

Each of the first to third light emitting structures EU1′ to EU3′ may include a light emitting layer generating light according to an applied current. The first light emitting structure EU1′ may include a first light emitting layer EML1′, a first electron transport unit ETU1′ and a first hole transport unit HTU1′. The first light emitting layer EML1′ may be disposed between the first electron transport unit ETU1′ and the first hole transport unit HTU1′. The second light emitting structure EU2′ may include a second light emitting layer EML2′, a second electron transport unit ETU2′, and a second hole transport unit HTU2′. The second light emitting layer EML2′ may be disposed between the second electron transport unit ETU2′ and the second hole transport unit HTU2′. The third light emitting structure EU3′ may include a third light emitting layer EML3′, a third electron transport unit ETU3′, and a third hole transport unit HTU3′. The third light emitting layer EML3′ may be disposed between the third electron transport unit ETU3′ and the third hole transport unit HTU3′.

Each of the first to third hole transport units HTU1′ to HTU3′ may include at least one of a hole injection layer and a hole transport layer, and further include a hole buffer layer, and an electron blocking layer, and the like, in some implementations. The first to third hole transport units HTU1′ to HTU3′ may have a same configuration or have different configurations.

Each of the first to third electron transport units ETU1′ to ETU3′ may include at least one of an electron injection layer and an electron transport layer, and further include an electron buffer layer, a hole blocking layer, and the like, in some implementations. The first to third electron transport units ETU1′ to ETU3′ may have a same configuration or have different configurations.

A first charge generation layer CGL1′ may be disposed between the first light emitting structure EU1′ and the second light emitting structure EU2′. A second charge generation layer CGL2′ may be disposed between the second light emitting structure EU2′ and the third light emitting structure EU3′.

In embodiments, the first to third light emitting layers EML1′ to EML3′ may generate lights of different colors. Lights respectively emitted from the first to third light emitting layers EML1′ to EML3′ may be mixed together, to be viewed as white light. For example, the first light emitting layer EML1′ may generate light of a blue color, the second light emitting layer EML2′ may generate light of a green color, and the third light emitting layer EML3′ may generate light of a red color.

In other embodiments, at least two light emitting layers among the first to third light emitting layers EML1′ to EML3′ may generate light of same color.

In some embodiments, one light emitting structure may be included in each of the first to third light emitting elements LD1 to LD3. The light emitting structures included in the first to third light emitting elements LD1 to LD3 may be configured to lights of different colors. For example, the light emitting structure of the first light emitting element LD1 may emit light of a red color, the light emitting structure of the second light emitting element LD2 may emit light of a green color, and the light emitting structure of the third light emitting element LD3 may emit light of a blue color. Unlike as shown in FIG. 6, portions of the light emitting structure EMS, which correspond to the first sub-pixel SPX1, the second sub-pixel SPX2, and the third sub-pixel SPX, may be separated from each other, and each of the portions of the light emitting structure EMS may be disposed in the opening OP of the upper layer PDL. At least a portion of color filters CF1 to CF3 may be omitted in some implementations of the embodiment.

The second electrode CE may be disposed on the light emitting structure EMS. The second electrode CE may be a cathode electrode of the light emitting element LD. The second electrode CE may be commonly provided in the first sub-pixel SPX1, the second sub-pixel SPX2, and a third sub-pixel SPX3. The second electrode CE may serve as a half mirror that allows light emitted from the light emitting structure EMS to be partially transmitted therethrough and allows light emitted from the light emitting structure EMS to be partially reflected therefrom.

The (1_1)th electrode AE1, a portion of the light emitting structure EMS, which overlaps the (1_1)th electrode AE1, and a portion of the second electrode CE, which overlaps the (1_1)th electrode AE1, may constitute the first light emitting element LD1. The (1_2)th electrode AE2, a portion of the light emitting structure EMS, which overlaps the (1_2)th electrode AE2, and a portion of the second electrode CE, which overlaps the (1_2)th electrode AE2, may constitute the second light emitting element LD2. The (1_3)th electrode AE3, a portion of the light emitting structure EMS, which overlaps the (1_3)th electrode AE3, and a portion of the second electrode CE, which overlaps the (1_3)th electrode AE3, may constitute the third light emitting element LD3.

A thin film encapsulation layer TFE may be disposed over the second electrode CE. The thin film encapsulation layer TFE may prevent oxygen and/or moisture from infiltrating into the light emitting element layer LDL.

An optical functional layer OFL may be disposed on the thin film encapsulation layer TFE. In embodiments, the optical functional layer OFL may be attached to the thin film encapsulation layer TFE through an adhesive layer APL. For example, the optical functional layer OFL may be separately manufactured to be attached to the thin film encapsulation layer TFE through the adhesive layer APL. The adhesive layer APL may further perform a function of protecting lower layers including the thin film encapsulation layer TFE.

The optical functional layer OFL may include a color filter layer CFL and a lens array LA. The color filter layer CFL may include first to third color filters CF1 to CF3 respectively corresponding to the first sub-pixel SPX1, the second sub-pixel SPX2, and the third sub-pixel SPX3. The first to third color filters CF1 to CF3 may allow lights having different wavelength ranges to pass therethrough. For example, the first to third color filters CF1 to CF3 may allow light red, green, and blue colors to pass therethrough, respectively.

In embodiments, the first to third color filters CF1 to CF3 may partially overlap each other in the boundary area BDA. In other embodiments, the first to third color filters CF1 to CF3 may be spaced apart from each other, and a black matrix may be provided between the first to third color filters CF1 to CF3.

The lens array LA may be disposed on the color filter layer CFL. The lens array LA may include first to third lenses LS1 to LS3 respectively corresponding to the first sub-pixel SPX1, the second sub-pixel SPX2, and the third sub-pixel SPX3. The first to third lenses LS1 to LS3 may respectively output lights emitted from the first to third light emitting elements LD1 to LD3 along intended paths, thereby improving light emission efficiency.

An overcoat layer OC may be disposed on the lens array LA. The overcoat layer OC may cover the optical functional layer OFL, the thin film encapsulation layer TFE, the light emitting structure EMS, and/or the pixel circuit layer PCL. The overcoat layer OC may include various materials suitable for protecting layers thereunder from a foreign substance such as dust or moisture. For example, the overcoat layer OC may include at least one of an inorganic insulating layer and an organic insulating layer. For example, the overcoat layer OC may include epoxy, but embodiments are not limited thereto. The overcoat layer OC may have a refractive index lower than a refractive index of the lens array LA.

A cover window CW may be disposed on the overcoat layer OC. The cover window CW is configured to protect layers thereunder. The cover window CW may have a refractive index higher than a refractive index of the overcoat layer OC. The cover window CW may include glass, but embodiments are not limited thereto. For example, the cover window CW may be an encapsulation glass configured to protect components disposed thereunder. In other embodiments, the cover window CW may be omitted.

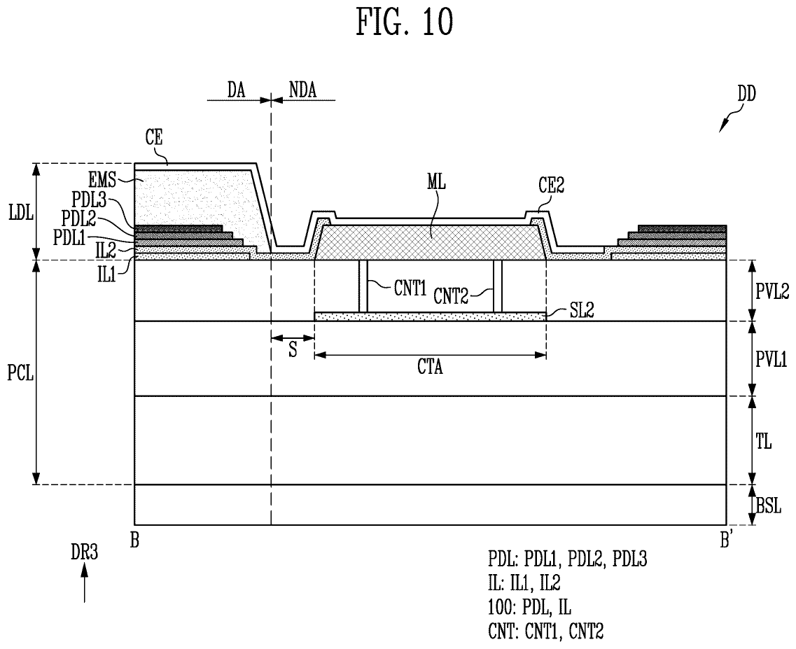

FIG. 9 is a schematic sectional view of the display device taken along line B-B′ shown in FIG. 1. That is, FIG. 9 illustrates a sectional view in the display area DA and the non-display area NDA of the display device DD. In FIG. 9, for clear and brief description, only the base layer BSL, the pixel circuit layer PCL, and the light emitting element layer LDL are illustrated. FIG. 10 is a schematic sectional view of a display device taken along the line B-B′ shown in FIG. 1 in accordance with another embodiment.

Hereinafter, components disposed in the non-display area NDA of the display device DD in accordance with the embodiment will be described with reference to FIGS. 9 to 10.

Referring to FIG. 9, the display device DD may include a connection electrode CE2 disposed in the non-display area NDA. The connection electrode CE2 may be connected to the second electrode CE disposed in the display area DA. The connection electrode CE2 may be integrally formed with the second electrode CE disposed in the display area DA. For example, the connection electrode CE2 may be a cathode electrode disposed in the non-display area NDA. The connection electrode CE2 may be formed with the second electrode CE disposed in the display area DA through a same process. For example, the second electrode CE may be deposited with the connection electrode CE2 through the same process, and include a same material as the connection electrode CE2.

The light emitting element layer LDL may further include a metal layer ML. The metal layer ML may be disposed on the pixel circuit layer PCL (or the second protective layer PVL2). The metal layer ML may be in contact with the pixel circuit layer PCL (or the second protective layer PVL2).

The metal layer ML may be formed with the first electrode AE disposed in the display area DA through a same process. For example, the metal layer ML may be deposited with the first electrode AE through the same process, and include a same material as the first electrode AE. For example, the metal layer ML may include at least one of Al, Ag, and Cu, and further include at least one of indium tin oxide (ITO), titanium (Ti), and titanium nitride (TiN).

In some embodiments, the metal layer ML may have a single-layer structure including at least one of Al, Ag, and Cu. In some embodiments, the metal layer ML may have a triple-layer structure in which a layer including at least one of Al, Ag, and Cu is stacked on a layer including at least one of indium tin oxide (ITO), titanium (Ti), and titanium nitride (TiN), and a layer including at least one of Al, Ag, and Cu is stacked on the layer including at least one of Al, Ag, and Cu. However, the embodiment is not limited thereto, and the metal layer ML may include a metal having a high reflectivity.

At least a portion of the metal layer ML may be in contact with at least a portion of the connection electrode CE2. At least a portion of a top surface of the metal layer ML may be in contact with at least a portion of the connection electrode CE2. The metal layer ML may be electrically connected to the connection electrode CE2.

The metal layer ML may have a thickness in a range of about 500 Å to about 1000 Å. The metal layer ML may have a thickness in a range of about 500 Å to about 1000 Å, and reduce a risk that the connection electrode CE2 will be disconnected.

The second protective layer PVL2 (or the pixel circuit layer PCL) may further include a second conductive layer SL2 and a contact hole CNT, which are disposed in the non-display area NDA.

The second conductive layer SL2 may be formed with the first conductive layer SL1 disposed in the display area DA through a same process. For example, the second conductive layer SL2 may be deposited with the first conductive layer SL1 through the same process, and accordingly, the second conductive layer SL2 and the first conductive layer SL1 may have a same material.

The second conductive layer SL2 may be electrically connected to the second electrode CE. The second conductive layer SL2 may be electrically connected to the metal layer ML, and the metal layer ML may be electrically connected to the connection electrode CE2. The connection electrode CE2 may be electrically connected to the second electrode CE. Accordingly, the second conductive layer SL2 may electrically connect the second power line PL2 (see FIG. 11) and the second electrode CE to each other. This will be described later with reference to FIG. 11.

The contact hole CNT may include a first contact hole CNT1 and a second contact hole CNT2. In some embodiments, the contact hole CNT may be provided in plurality. For example, six contact holes CNT may be formed. However, the number of contact holes CNT is not limited thereto. In some embodiments, the number of contact holes CNT may be changed.

The contact hole CNT may connect the metal layer ML and the pixel circuit layer PCL (e.g., the second conductive layer SL2) to each other while penetrating at least a portion of the second protective layer PVL2 (or the pixel circuit layer PCL).

The contact hole CNT may include a conductive material. The contact hole CNT may be filled with a conductive material. For example, the contact hole CNT may include tungsten (W). The contact hole CNT may include a conductive material, and electrically connect the metal layer ML and the second conductive layer SL2 to each other. The second electrode CE may be electrically connected to the second conductive layer SL2 through the metal layer ML.

As the second electrode CE is connected to the second conductive layer SL2 through the metal layer ML, the display device DD in accordance with the embodiment can prevent a risk that the second electrode CE will be disconnected. Experimentally, a surface of the contact hole CNT is not roughly flat in the contact area CTA, and therefore, a step difference may be formed. In a case that the metal layer ML does not exist, the second electrode CE is formed on a surface that is not flat. Therefore, the second electrode CE may be disconnected in the contact area CTA.

As compared with this, in the display device DD in accordance with the embodiment, the metal layer ML is disposed on the contact hole CNT, thereby providing a roughly flat surface. Accordingly, a risk that the second electrode CE will be disconnected in the contact area CTA can be reduced.

The insulating layer 100 may be disposed in the display area DA and the non-display area NDA. Hereinafter, the lower layer IL and the upper layer PDL, which are disposed in the display area DA, are defined as a first insulating layer, and the lower layer IL and the upper layer PDL, which are disposed in the non-display area NDA, are defined as a second insulating layer.

At least a portion of the second insulating layer may be connected to at least a portion of the first insulating layer. For example, at least a portion of the second insulating layer may be connected to at least a portion of the first insulating layer, so that at least a portion of the insulating layer 100 are formed in the display area DA and the non-display area NDA. For example, the first lower layer IL1 may be formed in the display area DA and the non-display area NDA. The first lower layer IL1 may extend from the display area DA to the non-display area NDA.

At least a portion of the second insulating layer may be in contact with at least a portion of the metal layer ML. At least a portion of the second insulating layer may be in contact with a side surface of the metal layer ML. At least a portion of the second insulating layer may overlap at least a portion of the metal layer ML in a plan view. At least a portion of the second insulating layer may expose the top surface of the metal layer ML. At least a portion of the second insulating layer, which is in contact with at least a portion of the metal layer ML, may be the first lower layer IL1.

For example, the first lower layer IL1 may be in contact with at least a portion of the metal layer ML. The first lower layer IL1 may be in contact with the side surface of the metal layer ML. The first lower layer IL1 may cover the side surface of the metal layer ML. The first lower layer IL1 may be in contact with at least a portion of the top surface of the metal layer ML. The first lower layer IL1 may cover at least a portion of the top surface of the metal layer ML. At least a portion of the first lower layer IL1 may overlap at least a portion of the metal layer ML in a plan view. An end portion (or edge) of the first lower layer IL1 may be in contact with the metal layer ML.

At least a portion of the second insulating layer may be in contact with the pixel circuit layer PCL (or the second protective layer PVL2). For example, the first lower layer IL1 may be in contact with the pixel circuit layer PCL (or the second protective layer PVL2). The first lower layer IL1 may be in contact with the pixel circuit layer PCL (or the second protective layer PVL2) in the non-display area NDA. In the display device DD in accordance with the embodiment, at least a portion of the second insulating layer may be disposed on the pixel circuit layer PCL (or the second protective layer PVL2) in an electrode deposition area S, and accordingly, a risk that the second electrode CE will be disconnected can be reduced.

The first lower layer IL1 may be in contact with the pixel circuit layer PCL (or the second protective layer PVL2) in the electrode deposition area S. At least a portion of the second insulating layer may be disposed on the bottom of at least a portion of the connection electrode CE2. For example, the first lower layer IL1 may be disposed on the bottom of the connection electrode CE2 in the electrode deposition area S. At least a portion of the first lower layer IL1 may be in contact with at least a portion of the connection electrode CE2.

Experimentally, when the second insulating layer is not disposed in the electrode deposition area S, the connection electrode CE2 may be deposited directly on the pixel circuit layer PCL in the electrode deposition area S. Due to a step difference of the surface of the pixel circuit layer PCL, the connection electrode CE2 may not be appropriately deposited (e.g., the connection electrode CE2 may not be deposited in a partial area), and be disconnected in the electrode deposition area S. On the other hand, in the display device DD in accordance with the embodiment, as at least a portion of the second insulating layer is disposed on the pixel circuit layer PCL in the electrode deposition area S, the step difference of the surface of the pixel circuit layer PCL can be reduced, and a risk that disconnection of the connection electrode CE2 will occur can be reduced.

The first lower layer IL1, the second lower layer IL2, the first upper layer PDL1, the second upper layer PDL2, and the third upper layer PDL3 may have end portions that are not in accord with each other. For example, the insulating layer 100 may have a stepped end portion. However, the embodiment is not limited thereto, and at least some of the first lower layer IL1, the second lower layer IL2, the first upper layer PDL1, the second upper layer PDL2, and the third upper layer PDL3 may have end portions that are in accord with each other.

In the above, although an embodiment in which the first lower layer IL1 extends from the display area DA to the non-display area NDA is illustrated in FIG. 9, the embodiment is not limited thereto.

For example, referring to FIG. 10, a second lower layer IL2 may extend from the display area DA to the non-display area NDA. The second lower layer IL2 may cover a first lower layer IL1 in the display area DA.

At least a portion of the second insulating layer, which is in contact with at least a portion of the metal layer ML, may be the second lower layer IL2. The second lower layer IL2 may be in contact with at least a portion of the metal layer ML. The second lower layer IL2 may be in contact with the side surface of the metal layer ML. The second lower layer IL2 may cover the side surface of the metal layer ML. The second lower layer IL2 may be in contact with the top surface of the metal layer ML. The second lower layer IL2 may cover at least a portion of the top surface of the metal layer ML. At least a portion of the second lower layer IL2 may overlap at least a portion of the metal layer ML in a plan view. An end portion (or edge) of the second lower layer IL2 may be in contact with the metal layer ML.

The second lower layer IL2 may be in contact with the pixel circuit layer PCL (or the second protective layer PVL2). The second lower layer IL2 may be in contact with the pixel circuit layer PCL (or the second protective layer PVL2) in the non-display area NDA. The second lower layer IL2 may be in contact with the pixel circuit layer PCL (or the second protective layer PVL2) in the electrode deposition area S. The second lower layer IL2 may be disposed on the bottom of the connection electrode CE2 in the electrode deposition area S. At least a portion of the second lower layer IL2 may be in contact with at least a portion of the connection electrode CE2.

In the above, although an embodiment in which a portion of the lower layer IL extends from the display area DA to the non-display area NDA is illustrated in FIGS. 9 and 10, the embodiment is not limited thereto. In some embodiments, one of the first upper layer PDL1, the second upper layer PDL2, and the third upper layer PDL3 may extend from the display area DA to the non-display area NDA.

For example, a first upper layer PDL1 may extend from the display area DA to the non-display area NDA. The first upper layer PDL1 may cover the lower layer IL in the display area DA.

At least a portion of the second insulating layer, which is in contact with at least a portion of the metal layer ML, may be the first upper layer PDL1. The first upper layer PDL1 may be in contact with at least a portion of the metal layer ML. The first upper layer PDL1 may be in contact with the side surface of the metal layer ML. The first upper layer PDL1 may cover the side surface of the metal layer ML. The first upper layer PDL1 may be in contact with at least a portion of the top surface of the metal layer ML. At least a portion of the first upper layer PDL1 may overlap at least a portion of the metal layer ML in a plan view. An end portion (or edge) of the first upper layer PDL may be in contact with the metal layer ML.

The first upper layer PDL1 may be in contact with the pixel circuit layer PCL (or the second protective layer PVL2). The first upper layer PDL1 may be in contact with the pixel circuit layer PCL (or the second protective layer PVL2) in the non-display area NDA. The first upper layer PDL1 may be in contact with the pixel circuit layer PCL (or the second protective layer PVL2) in the electrode deposition area S. The first upper layer PDL1 may be disposed on the bottom of the connection electrode CE2 in the electrode deposition area S. At least a portion of the first upper layer PDL1 may be in contact with at least a portion of the connection electrode CE2.

In some embodiments, a second upper layer PDL2 may extend from the display area DA to the non-display area NDA. The second upper layer PDL2 may cover the first upper layer PDL1 and the lower layer IL in the display area DA.

At least a portion of the second insulating layer, which is in contact with at least a portion of the metal layer ML, may be the second upper layer PDL2. The second upper layer PDL2 may be in contact with at least a portion of the metal layer ML. The second upper layer PDL2 may be in contact with the side surface of the metal layer ML. The second upper layer PDL2 may cover the side surface of the metal layer ML. The second upper layer PDL2 may be in contact with at least a portion of the top surface of the metal layer ML. The second upper layer PDL2 may cover at least a portion of the top surface of the metal layer. At least a portion of the second upper layer PDL2 may overlap at least a portion of the metal layer ML in a plan view. An end portion (or edge) of the second upper layer PDL2 may be in contact with the metal layer ML.

The second upper layer PDL2 may be in contact with the pixel circuit layer PCL (or the second protective layer PVL2). The second upper layer PDL2 may be in contact with the pixel circuit layer PCL (or the second protective layer PVL2) in the non-display area NDA. The second upper layer PDL2 may be in contact with the pixel circuit layer PCL (or the second protective layer PVL2) in the electrode deposition area S. The second upper layer PDL2 may be disposed on the bottom of the connection electrode CE2 in the electrode deposition area S. At least a portion of the second upper layer PDL2 may be in contact with at least a portion of the connection electrode CE2.

In some embodiments, a third upper layer PDL3 may extend from the display area DA to the non-display area NDA. The third upper layer PDL3 may cover the second upper layer PDL2, the first upper layer PDL1, and the lower layer IL.

At least a portion of the second insulating layer, which is in contact with at least a portion of the metal layer ML, may be the third upper layer PDL3. The third upper layer PDL3 may be in contact with at least a portion of the metal layer ML. The third upper layer PDL3 may be in contact with the side surface of the metal layer ML. The third upper layer PDL3 may cover the side surface of the metal layer ML. The third upper layer PDL3 may be in contact with at least a portion of the top surface of the metal layer ML. The third upper layer PDL3 may cover at least a portion of the top surface of the metal layer ML. At least a portion of the third upper layer PDL3 may overlap at least a portion of the metal layer ML in a plan view. An end portion (or edge) of the third upper layer PDL3 may be in contact with the metal layer ML.

The third upper layer PDL3 may be in contact with the pixel circuit layer PCL (or the second protective layer PVL2). The third upper layer PDL3 may be in contact with the pixel circuit layer PCL (or the second protective layer PVL2) in the non-display area NDA. The third upper layer PDL3 may be in contact with the pixel circuit layer PCL (or the second protective layer PVL2) in the electrode deposition area S. The third upper layer PDL3 may be disposed on the bottom of the connection electrode CE2 in the electrode deposition area S. At least a portion of the third upper layer PDL3 may be in contact with at least a portion of the connection electrode CE2.

Hereinafter, an electrical connection relationship between circuit elements will be described with reference to FIG. 11. FIG. 11 is a schematic block diagram illustrating an electrical connection structure of a light emitting element in accordance with an embodiment.

Referring to FIG. 11, a sub-pixel SPX may include a pixel circuit PXC configured to drive a light emitting element LD.

The pixel circuit PXC may include at least one circuit element. For example, the pixel circuit PXC may include transistors and a storage capacitor. For example, the pixel circuit PXC may include a driving transistor, a switching transistor, and a storage capacitor. However, the embodiment is not necessarily limited thereto.

The pixel circuit PXC may be electrically connected to a scan line SL and a data line DL. The scan line SL may supply a scan signal to the pixel circuit PXC. In some embodiments, the scan line SL may be electrically connected to a gate electrode of the switching transistor of the pixel circuit PXC. The light emitting element LD may be configured to emit light corresponding to a data signal provided from the data line DL.

The pixel circuit PXC may be electrically connected to a first power line PL1 and a second power line PL2. For example, a first electrode AE of the light emitting element LD may be electrically connected to the pixel circuit PXC and the first power line PL1, and a second electrode CE of the light emitting element LD may be electrically connected to the second power line PL2. The first power line PL1 and the second power line PL2 may be disposed on the base layer BSL.

A power source of the first power line PL1 and a power source of the second power line PL2 may have different potentials. For example, the power source of the first power line PL1 may be a high-potential pixel power source supplied with a power source from a first voltage potential VDD, and the power source of the second power line PL2 may be a low-potential pixel power source supplied with a power source from a second voltage potential VSS. A potential difference between the power source of the first power line PL1 and the power source of the second power line PL2 may be set equal to or higher than a threshold voltage of light emitting elements LD.

The first power line PL1 may be electrically connected to the pixel circuit PXC (e.g., the driving transistor). The second power line PL2 may be electrically connected to a cathode electrode (e.g., the second electrode CE) of the light emitting element LD.

In some embodiments, the second power line PL2 may be electrically connected to the second electrode CE. For example, the second electrode CE may be applied with a power source through the second power line PL2 disposed in the non-display area NDA. In some embodiments, the second electrode CE disposed in the display area DA may be adjacent to the connection electrode CE2 disposed in the non-display area NDA. The second electrode CE disposed in the display area DA may be electrically connected to the connection electrode CE2 disposed in the non-display area NDA. The connection electrode CE2 in the non-display area DA may be electrically connected to the second conductive layer SL2 through the metal layer ML. In some embodiments, the above-described second conductive layer SL2 may be adjacent to the second power line PL2. The second conductive layer SL2 may be electrically connected to the second power line PL2. Accordingly, the second power line PL2 may apply a power source to the connection electrode CE2 through the second conductive layer SL2.

Accordingly, the second electrode CE formed in the display area DA may be electrically connected to the second power line PL2 in the non-display area NDA. As described above, since the second electrode CE in the display area DA and the second power line PL2 are electrically connected to each other, a power source provided by the second power line PL2 may be applied to the entire display area DA.

Light emitting elements LD may be connected in a forward direction between the first power line PL1 and the second power line PL2, to respectively form effective light sources. These effective light sources gather to constitute the light emitting elements LD of the sub-pixel SPX.

The light emitting elements LD may emit light with a luminance corresponding to a driving current supplied through the pixel circuit PXC. The pixel circuit PXC may supply a driving current corresponding to the data signal to the light emitting element LD during each frame period. The light emitting element LD may emit light with a luminance corresponding to a current flowing therethrough.

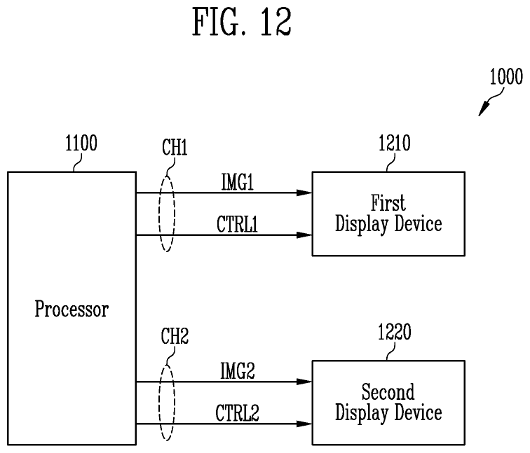

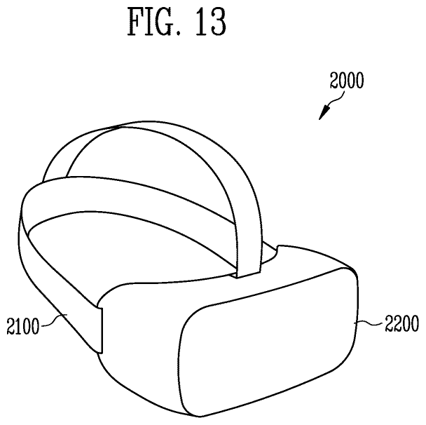

Hereinafter, a display system 1000 to which the display device DD can be applied will be described with reference to FIGS. 12 and 13.

FIG. 12 is a schematic block diagram illustrating a display system in accordance with an embodiment. FIG. 13 is a schematic perspective view illustrating an application example of the display system shown in FIG. 12.

Referring to FIG. 12, the display system 1000 may include a processor 1100 and one or more display devices 1210 and 1220.

The processor 1100 may perform various tasks and various calculations. In embodiments, the processor 1100 may include an Application Processor (AP), a Graphics Processing Unit (GPU), a microprocessor, a Central Processing Unit (CPU), and the like. The processor 1100 may be connected to other components of the display system 1000 through a bus system to control the components of the display system 1000.

In FIG. 12, it is illustrated that the display system 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device DD described with reference to FIG. 1. The first image data IMG1 and the first control signal CTRL1 may be respectively provided as the input image data and the control signal to the display device DD which are shown in FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device DD described with reference to FIG. 1.

The display system 1000 may include a computing system for providing an image display function, such as a portable computer, a mobile phone, a smartphone, a tablet personal computer (PC), a smart watch, a watch phone, a portable multimedia player (PMP), a navigation system, or an ultra mobile computer (UMPC). Also, the display system 1000 may include at least one of a head mounted display (HMD) device, a virtual reality (VR) device, a mixed reality (MR) device, and an augmented reality (AR) device.

Referring to FIG. 13, the display system 1000 shown in FIG. 12 may be applied to a head mounted display device 2000. The head mounted display device 2000 may be a wearable electronic device that can be worn on a head of a user.

The head mounted display device 2000 may include a head mounting band 2100 and a display device accommodating case 2200. The head mounting band 2100 may be connected to the display device accommodating case 2200. The head mounting band 2100 may include a horizontal band and/or a vertical band, used to fix the head mounted display device 2000 to the head of the user. The horizontal band may be configured to surround a side portion of the head of the user, and the vertical band may be configured to surround an upper portion of the head of the user (e.g., the forehead of the user). However, embodiments are not limited thereto. For example, the head mounting band 2100 may be implemented in the form of a glasses frame, a helmet, or the like.

The display device accommodating case 2200 may accommodate the first and second display devices 1210 and 1220 shown in FIG. 12. The display device accommodating case 2200 may further accommodate the processor 1100 shown in FIG. 12.

In accordance with the embodiments described hereinabove, there can be provided a display device capable of reducing a risk that an electrode (e.g., a cathode electrode) will be disconnected.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of this application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a display area in which a pixel is disposed and a non-display area that corresponds to an area separate from the display area;
a pixel circuit layer including a pixel circuit;
a first electrode disposed on the pixel circuit layer;
an insulating layer having at least a portion exposing the first electrode;
a second electrode disposed in the display area; and
a connection electrode integrally formed with the second electrode, the connection electrode disposed in the non-display area, wherein
the insulating layer includes:
a first insulating layer disposed in the display area; and
a second insulating layer disposed in the non-display area, and
the second insulating layer is in contact with at least a portion of the connection electrode.

2. The display device of claim 1, further comprising:
a metal layer disposed in the non-display area, the metal layer being disposed on the pixel circuit layer, wherein
at least a portion of the second insulating layer overlaps at least a portion of the metal layer in a plan view,
the second insulating layer exposes a top surface of the metal layer, and
an end portion of the second insulating layer is in contact with the connection electrode.

3. The display device of claim 2, wherein the connection electrode is in contact with at least a portion of the top surface of the metal layer.

4. The display device of claim 2, wherein the metal layer includes at least one of Al, Ag, and Cu.

5. The display device of claim 2, wherein the metal layer has a thickness in a range of about 500 Å to about 1000 Å.

6. The display device of claim 1, wherein
the insulating layer includes a lower layer and an upper layer disposed on the lower layer, and
at least a portion of the insulating layer extends from the display area to the non-display area.

7. The display device of claim 6, wherein
the lower layer includes:
a first lower layer; and
a second lower layer disposed on the first lower layer, and
the upper layer includes:
a first upper layer;
a second upper layer disposed on the first upper layer; and
a third upper layer disposed on the second upper layer.

8. The display device of claim 7, wherein
each of the first lower layer, the second lower layer, the first upper layer, the second upper layer, and the third upper layer includes at least one of silicon oxide (SiOₓ) and silicon nitride (SiNₓ), and
each of the first lower layer, the second lower layer, the first upper layer, the second upper layer, and the third upper layer has a thickness in a range of about 100 Å to about 600 Å.

9. The display device of claim 1, wherein at least a portion of the second insulating layer is connected to at least a portion of the first insulating layer, so that at least a portion of the insulating layer is disposed in the display area and the non-display area.

10. The display device of claim 1, wherein
the pixel circuit layer includes:
a first protective layer; and
a second protective layer disposed on the first protective layer,
the second protective layer is disposed at an uppermost portion of the pixel circuit layer, and
at least a portion of the second insulating layer is in contact with the second protective layer.

11. The display device of claim 2, wherein at least a portion of the second insulating layer covers a side surface of the metal layer.

12. The display device of claim 2, wherein
the pixel circuit layer includes:
a contact hole penetrating at least a portion of the pixel circuit layer;
a first conductive layer disposed in the display area; and
a second conductive layer disposed in the non-display area, and
the metal layer is electrically connected to the second conductive layer through the contact hole.

13. A display device comprising:
a display area in which a pixel is disposed and a non-display area that corresponds to an area separate from the display area;
a pixel circuit layer including a pixel circuit;
a first power line and a second power line, electrically connected to the pixel circuit;
a first electrode disposed on the pixel circuit layer;
an insulating layer having at least a portion exposing the first electrode;
a second electrode disposed in the display area; and
a metal layer disposed on the pixel circuit layer in the non-display area, wherein
the insulating layer includes:
a first insulating layer disposed in the display area; and
a second insulating layer disposed in the non-display area,
the second insulating layer is in contact with at least a portion of the metal layer, and
the non-display area includes a contact area in which the second power line and a connection electrode are electrically connected to each other.

14. The display device of claim 13, further comprising:
the connection electrode integrally formed with the second electrode, the connection electrode being disposed in the non-display area, wherein
the connection electrode is in contact with at least a portion of a top surface of the metal layer, and
the contact area includes:
a first contact area disposed at a first side of the display area;
a second contact area disposed at a second side of the display area;
a third contact area disposed at a third side of the display area; and
a fourth contact area disposed at a fourth side of the display area.

15. The display device of claim 14, wherein
the metal layer includes at least one of Al, Ag, and Cu,
the metal layer has a thickness in a range of about 500 Å to about 1000 Å, and
the contact area includes:
a fifth contact area disposed between the first contact area and the second contact area; and
a sixth contact area disposed between the third contact area and the fourth contact area.

16. The display device of claim 13, wherein
the insulating layer includes a lower layer and an upper layer disposed on the lower layer,
the lower layer includes:
a first lower layer; and
a second lower layer disposed on the first lower layer,
the upper layer includes:
a first upper layer;
a second upper layer disposed on the first upper layer; and
a third upper layer disposed on the second upper layer, and
the contact area surrounds at least a portion of the display area.

17. The display device of claim 16, wherein each of the first lower layer, the second lower layer, the first upper layer, the second upper layer, and the third upper layer includes at least one of silicon oxide (SiOₓ) and silicon nitride (SiNₓ), and has a thickness in a range of about 100 Å to about 600 Å.

18. The display device of claim 13, wherein
at least a portion of the second insulating layer is connected to at least a portion of the first insulating layer, so that at least a portion of the insulating layer is disposed in the display area and the non-display area, and
at least a portion of the second insulating layer overlaps at least a portion of the metal layer in a plan view.

19. The display device of claim 13, wherein
the pixel circuit layer includes:
a contact hole penetrating at least a portion of the pixel circuit layer;
a first conductive layer disposed in the display area; and
a second conductive layer disposed in the non-display area, and
the metal layer is electrically connected to the second conductive layer through the contact hole.

20. The display device of claim 13, wherein the non-display area surrounds at least a portion of the display area.
